(19) United States
(12) Patent Application Publication
(10) Pub. No.: US 2009/0162571 A1
(43) Pub. Date: Jun. 25, 2009

(54) Method and Device for Producing Process Gases for Vapor Phase Deposition

(75) Inventors: Daniel Edward Haines, Lake Ariel, PA (US); Matthias Bicker, Mainz (DE); Stefan Bauer, Alzey (DE); Hartmut Bauch, Ober-Olm (DE); Manfred Lohmeyer, Nackenheim (DE)

Correspondence Address: DeMont & Breyer, LLC, 100 Commons Way, Ste. 250, Holmdel, NJ, 07733, US

(73) Assignee: SCHOTT AG, Mainz (DE)

(21) Appl. No.: 12/340,663

(22) Filed: Dec. 20, 2008

(30) Foreign Application Priority Data
Dec. 21, 2007 (DE) 10 2007 062 977.1

(51) Int. Cl. C23C 16/448; B05C 11/00

(52) U.S. Cl. 427/569; 427/248.1; 427/255.28; 118/663

(57) ABSTRACT

The invention relates to a method for producing layers on work pieces (30) in which at least one component for producing the layer is metered, wherein this component is located in liquid phase during the metering and is transformed at least partially into a different aggregate state in a subsequent processing step.

The invention relates in general to the deposition of functional layers on substrates. In particular, the invention relates to chemical vapor phase deposition and to the metering of the materials used for vapor phase deposition.

Alkane and polyamine solvent compositions are known from US 2001/0004470 A1. The solvent composition is used for supplying a fluid from organometallic precursor substances for chemical vapor phase deposition, in order to deposit, for example, so-called SBT layers (SrBi₂Ta₂O₉ layers) for data memory. In order to transform the precursors into the gas phase, flash vaporization is used. In this method, partial vaporization is realized by reducing the pressure.

DE 199 60 333 A1 describes a device for producing a gas mixture composed of HMDSO (hexamethyldisiloxane) and oxygen as the process gas for plasma coating. For this purpose, several filler packings are arranged one above the other in an elongated, vertical, coolable column. The upper region of the column has an inlet downcomer into the column and a gas outlet. Furthermore, devices for measuring the temperature, the pressure, and the quantity of output gas are provided.

Another previously used system for evaporating precursors is a so-called bubbler. In this system, the carrier gas is bubbled into the liquid precursor. The precursor here evaporates into gas bubbles and is transported along with the carrier gas.

It has been shown, however, that bubblers are difficult to set in terms of production stability with respect to the precursor flow, because pressure, temperature, and precursor gas flow simultaneously have a large effect on the evaporation rate. For example, only a small change in the bubble size can have a large effect on the precursor concentration due to the resulting change in surface area available for evaporation. This is also the case in other evaporators known from the prior art. For example, in a column like that proposed in DE 199 60 333 A1, the precursor content of the process gas is dependent on the temperature of the column. Here, the pressure prevailing in the column is also an influence, as in flash evaporation.

Therefore, the invention is based on the task of providing a more controllable metering of precursor substances for chemical vapor phase deposition that is less susceptible to fluctuations in the processing parameters. The realization of this task according to the invention is presented in the independent claims. Advantageous configurations and improvements of the invention are the subject matter of the subordinate claims.

Accordingly, the invention presents a method for producing layers on work pieces in which at least one component for producing the layer, in particular, a layer-forming component, is metered, wherein this component is located in a liquid phase during the metering and is transformed at least partially into a different aggregate state in a subsequent processing step. In this way, the layer is made from the component loaded in the different aggregate state. As different aggregate states, in particular, gas phase and plasma can be considered.

The invention is here suitable for various chemical vapor phase deposition methods (CV methods). In addition to a chemical vapor phase deposition under vacuum or low-pressure conditions, atmospheric pressure CVD methods, such as thermal CVD under atmospheric pressure or atmospheric pressure plasma deposition may also be used. Other methods are flame pyrolysis or so-called “combustion CVD” (CCVD, combustion CVD).

In particular, the invention provides a method for the vapor phase deposition of layers on work pieces, wherein
a liquid reservoir is provided with a first liquid process gas component, and
the liquid process gas component is led via a metering device into an evaporator (2), wherein
the first liquid process gas component (34) evaporates in the evaporator and is transformed into the gas phase, and is fed to a reactor (20), and wherein
by means of an energy source, a reactive zone is generated with the first process gas component in the filled region of the reactor, wherein
a coating is deposited on the work piece with the reaction products of the first process gas component forming in the reactive zone. In this way, the mass flow of the first process gas component into the reactor is controlled by means of a control device acting on the metering device through a control of the flow of the liquid process gas component into the evaporator.

In one especially preferable improvement, a method for chemical vapor phase deposition is provided that is preferably for plasma-supported chemical vapor phase deposition of layers on work pieces. For this purpose,
a liquid reservoir is provided with a first liquid process gas component, and
the liquid process gas component is led into an evaporator, wherein
the first liquid process gas component evaporates in the evaporator and is transformed into the gas phase, and wherein
a reactor with a work piece to be coated is evacuated by means of a pump,
the first gaseous process gas component is fed to the evacuated region of the reactor, and
a plasma in the evacuated region of the reactor filled with the first process gas component is ignited by means of an electromagnetic field, wherein
a coating is deposited on the work piece with the reaction products of the first process gas component forming in the plasma. In this way, the mass flow of the first process gas component into the reactor is controlled, in turn, by means of the control device by a control of the flow of the liquid process gas component into the evaporator. In this embodiment, a reactive zone is generated accordingly in the form of a plasma. However, the invention can also be definitely used for other types of reactive zones. Deposition through thermal CVD is conceivable, for example. In this way, a heated zone is generated in which the reaction products form. Not only CVD, but also reactive PVD falls under vacuum deposition as a field of application of the invention. For this purpose, a layer is vacuum evaporated or sputtered, wherein at least one precursor or one first component is fed to the vacuum or low-pressure environment.

The invention is not limited to specific work pieces. Both flat and also voluminous work pieces, in particular, also hollow bodies, can be coated. In the latter case, in particular, inner coating is also conceivable.

In the case of vacuum deposition, as, in particular, for chemical vapor deposition under low-pressure or vacuum conditions, the entire reactor does not have to be evacuated in all cases. For example, if only the inside of a hollow body-shaped work piece is to be coated, the work piece can be connected in a gas-tight way in the reactor to the pump and the feed line and can be evacuated on the inside. The environment can optionally remain at normal pressure or can also be evacuated separately.

It has been shown that an exact metering of also very small mass flows is possible in liquid form. The mass flow of the liquid process gas component set by the metering here lies, according to one improvement of the invention, in the range of 0.0005-2000 g/h, preferably in the range of 0.05-50 g/h, especially preferably in the range of 0.1-20 g/h. This is especially important if deposition is performed from the gas phase and/or a plasma. The transformation into the gas phase produces a large increase in volume. Consequently, inaccuracies in the mass flow of the liquid component are considerably amplified in the mass flow of gaseous component. However, it has been shown that the mass flow of a gaseous component can be controlled very exactly and stably by means of the invention. The mass flow can also be controlled equivalently as a volume flow. Preferred ranges of the volume flow of the liquid component here lie in the range of 5 nanoliters/min-1000 microliters/min, preferably in the range of 10 nanoliters/min-100 microliters/min, especially preferably in the range of 20 nanoliters/min-10 microliters/min.

In order to achieve the desired metering accuracy of the component transformed into the different aggregate state, in particular, into the gaseous state, according to yet another improvement of the invention, in particular, a metering accuracy of the liquid volume flow is provided in the range below 30 μL/min, preferably in the range below 3 μL/min, especially preferably below 0.3 μL/min.

Furthermore, in the case of plasma deposition, a pulsed plasma is used for deposition in an especially preferred way.

The corresponding device according to the invention for carrying out the method for depositing layers onto work pieces comprises, accordingly,
a liquid reservoir for a first liquid process gas component,
a metering device,
an evaporator,
a line for supplying the liquid process gas component (34) to the evaporator,
a reactor constructed for receiving a work piece to be coated,
a gas outlet that is connected to the reactor and by means of which the volatile decomposition products can be removed from the coating region of the reactor,
a feed line for supplying the first gaseous process gas component evaporated in the evaporator to the reactor, and
an energy source that is connected to the reactor, in order to generate a reactive zone in the region of the reactor filled with the first process gas component, so that with the reaction products of the first process gas component forming in the reactive zone, a coating is deposited on the work piece, and also a control device for controlling the mass flow of the first process gas component into the reactor, wherein the control device is constructed to control the flow of the liquid process gas component into the evaporator by means of the metering device for setting the mass flow.

The energy source can also be controlled preferably by means of a control device or another regulation or control device.

In the case of a device for plasma-supported vapor phase deposition of layers on work pieces, it comprises, accordingly,
a liquid reservoir for a first liquid process gas component,
an evaporator,
a line for supplying the liquid process gas component to the evaporator,
a reactor constructed for receiving a work piece to be coated,
a pump connected to the reactor, in order to evacuate the coating region of the reactor,
a feed line for supplying the first gaseous process gas component evaporated in the evaporator to the reactor, and
a source for electromagnetic fields that is connected to the reactor, in order to ignite a plasma in the evacuated region of the reactor filled with the first process gas component by means of the electromagnetic field generated by the source, so a coating is deposited on the work piece with the reaction products of the first process gas component forming in the plasma. There is, in turn, a control device for controlling the mass flow of the first process gas component in the reactor that is constructed to control the flow of liquid process gas component into the evaporator for setting the mass flow.

A source for electrostatic fields is also understood as a source for electromagnetic fields. This can be used, for example, for layer deposition by means of a glow discharge plasma.

In addition to plasma-supported chemical vapor phase deposition, however, the invention can also be used for other types of chemical vapor phase deposition, that is, in general, for CVD. According to the deposition process, the source for electromagnetic fields may be omitted, accordingly. As an example here, thermal CVD is mentioned.

To generate a flow of the first liquid process gas component through the line into the evaporator, a fluid feeding device, such as, for example, a pump or a pressurized reservoir can be provided. In the latter case, a gas can be filled into the reservoir, for example, in addition to the liquid process gas component, so that the reservoir is under high pressure relative to the evaporator. This is also the case, for example, if a low pressure is generated or maintained in the evaporator. In this case, the first process gas component is also fed into the evaporator when—assuming sufficient low pressure—the reservoir is kept at normal pressure. Another possibility is to use hydrostatic pressure generated due to the force of gravity and the arrangement of the reservoir relative to the evaporator. For this purpose, the liquid level in the reservoir is arranged above the inlet point of the line into the evaporator.

According to the invention, a liquid metering system is provided accordingly for a controlled metering of organic and/or organometallic substances.

It is surprising that the liquid metering according to the invention enables a very exact, reproducible control of the mass flow and associated with this also the properties of the deposited layers. One should expect that a liquid may be metered more poorly before the evaporation, because a large increase in volume is produced with the evaporation. Therefore, for comparable accuracy, the metering of the liquid requires significantly smaller absolute errors.

It has been shown, however, that the deposition of layers can be controlled very precisely with the method according to the invention. The fluctuations of the mass flow of the process gas component or components is very low, which can also be demonstrated with reference to the deposited layers. For example, the layers exhibit low light scattering and all layer properties have proven to be precisely reproducible.

The method according to the invention represents a very simple way for plasma coating or for the preparation of precursor gases compared with bubblers that were typically used before. Through the simple construction, the system according to the invention is also more economical than systems with bubblers as the gas generator.

In order to achieve quick evaporation of the first process gas component, it is especially advantageous when the first liquid process gas component is sprayed with a nozzle in the evaporator. In general, the evaporation rate of the liquid process gas component in the evaporator can be set higher than the inflow of the liquid process gas component. In this way, collection of large quantities of liquid material in the evaporator is avoided. The evaporator is thus operated, in contrast, for example, to a bubbler, to some extent “dry.” Therefore, because the liquid material introduced into the evaporator is evaporated very quickly, a change in the flow in the feed line directly influences the mass flow of the gaseous precursor in the evaporator, so that a nearly delay-free control is possible by means of the liquid metering.

The first process gas component is preferably mixed with at least a second process gas component to form a process gas mixture. Especially suitable here are inert gases, such as, in particular, noble gases. Such gases simplify, among other things, the ignition of the plasma and allow the plasma to be maintained at lower precursor concentrations. Alternatively, however, nitrogen can also be used as the inert gas. Alternatively or additionally, a reactive gas, such as, for example, oxygen, ozone, hydrogen, ammonia, or a hydrocarbon may also be used.

It has also proven especially advantageous when mixing of the first and the second process gas components is performed in the evaporator. For this purpose, a feed line to the evaporator is provided for a second process gas component stored in a reservoir, in order to mix the first and the second process gas components in the evaporator to form a process gas mixture. In the evaporator, the mixture has already proven to be favorable for preventing or reducing fluctuations in the mass flow of the evaporated precursor that may be generated through individual evaporating drops.

In order to control the flow of the first liquid process gas component, instantaneous flow is determined by means of a suitable device. The flow is then input as a parameter into the control process controlled by the control device. Preferably, the flow of the liquid process gas component is measured with a mass flow sensor in its feed line to the evaporator. This is arranged in the feed line of the first liquid process gas component to the evaporator and connected to the control device.

The metered liquid component does not have to be pure according to another improvement of the invention. Instead, it is also conceivable to meter fluidly a mixture composed of at least two components. For the evaporation of a mixture with a bubbler, the concentration of the components depends on their vapor pressures. Correspondingly, by means of the invention, due to the quick and complete evaporation of the components in the evaporator for mixture, the ratio of quantities is essentially independent of vapor pressure, as long as larger quantities of liquid do not collect in the evaporator.

A suitable measurement principle is the measurement of the mass flow with reference to the heat transport by the fluid. Sensors of this type are known, for example, from DE 2350848 A. In particular, the temperature difference can be determined between two measurement points spaced apart along the direction of flow of the first liquid process gas component. For this purpose, two temperature measurement sensors with which a temperature difference is determined are provided spaced apart along the direction of flow of the first liquid process gas component. The greater the temperature different is, the higher the mass flow also. In addition, a device for changing the temperature is provided, in order to generate a temperature gradient in the flowing liquid. In the simplest case, the liquid can flow past a heating element. The heating device can also heat one or two temperature measurement sensors. For example, an energized resistive element or thermocouple may be used as a temperature sensor with which the temperature is measured and the liquid is heated simultaneously.

The pressure in the reactor during the coating is controlled according to a preferred improvement of the invention by means of a choke in the discharge line from the reactor to the pump that communicates with the control device or is connected to the control device and thus can be controlled by the control device. Accordingly, the control device is constructed to regulate the pressure in the reactor by means of the choke.

A control of the process gas quantity present in the reactor can then be realized by controlling the pressure on one side and controlling the mass flow by the liquid metering according to the invention on the other side. A regulated throttling of the process gas quantity between the reactor and evaporator is then not required.

By means of the invention, various functional coatings can be produced on flat and three-dimensionally shaped or molded substrates. One special advantage is the very good suitability for the production of functional coatings made from precursor substances with low vapor pressure. With the method, in a process suitable for production, first process gas components can be evaporated and fed to the reactor that has, at room temperature, a vapor pressure less than 200 mbar, preferably less than 80 mbar, especially preferably less than 10 mbar. This also applies for components that have, at a temperature of 130° C., a vapor pressure less than 10,000 mbar, preferably less than 1300 mbar, especially preferably less than 50 mbar. The invention represents a very efficient method for also reaching high mass flows with precursors that exhibit a low vapor pressure or a high boiling point.

Another special advantage of the invention lies in the fact that compared with a bubbler, the first liquid process gas component in the liquid reservoir can be stored at a temperature below 100° C., preferably below 50° C., especially preferably without additional heating at ambient temperature. The storage of the precursor at room temperature here leads to lower production costs and undesired changes of the precursor are prevented that could result due to long heating. The liquid reservoir may even be cooled. Both allow the use of metastable substances as precursors that are not stable for a long time at the vaporization temperature in the evaporator or at a temperature of 130° C.

In particular, precursors can be used and precisely metered that have both a low vapor pressure and are also metastable. With a bubbler, this would not be possible, because the precursor is kept in the liquid reservoir of the evaporator for a long time at the vaporization temperature.

In general, an acyclical polyether, such as mono-, di-, tri-, tetra-, penta-, or hexaethylene glycol dimethyl ether may be used as the first process gas component. One example here is the liquid metering of tetraethylene glycol dimethyl ether (“tetraglyme”) as a precursor or first process gas component or constituent of the process gas component. This substance has a relatively low vapor pressure. A liquid metering device may be used that has a mass flow sensor, a metering valve controlled with an electronic control device, an inert carrier gas, and an evaporator, in order to transform the precursor into the gas phase. By means of this device, pharmaceutical glass vials are coated on the inside by plasma polymerization of the tetraethylene glycol dimethyl ether. The coated internal surfaces of the vials then exhibit a very low protein adsorption compared with uncoated glass vials. With tetraethylene glycol dimethyl ether as the precursor, a polyethylene glycol-containing or polyethylene glycol-like coating (“PEG coating”) may then be deposited on the work piece. Such a layer is an example for a protein-rejecting or protein-repellant coating. In the field of pharmaceutical packaging, special attention is also placed on such coatings. Proteins often tend toward denaturing on glass surfaces, which can be prevented or at least considerably slowed with a protein-repellant coating, such as a PEG coating that can be produced according to the invention. Therefore, in pharmaceutical containers coated in this way, sensitive, protein-based drugs, such as inoculations, can be better stored.

In general, pharmaceutical or medical products and also products for diagnostics applications can be coated according to the invention for improving the functionality. Such products can be tubes, pharmaceutical sprayers, or associated elastomer components, cartridges, or bottles. In the case of products for diagnostics applications, among other things, microarrays are imagined. Advantages are also given for the deposition of layers made from precursors with low vapor pressure. These process gas components can be handled more easily due to the ability to keep the reservoir at a lower temperature.

The invention can be used for substrates made from glass, glass ceramic, polymers, and elastomers, for example, for coating glass tubes or pharmaceutical packaging. As examples for pharmaceutical packaging, vials, cartridges, sprayers, rubber stoppers, or elastomer-coated sealing surfaces are named. The invention is also suitable for the coating of metallic surfaces, such as hollow needles. Coated objects can then have reduced friction and an improved barrier effect as advantageous properties.

Likewise, optical functions can be realized, such as optical filter coatings, reflective coatings, and anti-reflection coatings and transparent barrier layers on illuminating elements.

Possible, advantageous properties of coatings that can be produced according to the invention are listed again below:
i) Modification of the adsorption of macromolecules, preferably such that the macromolecules are rejected or repelled,
ii) Change in friction or the coefficient of friction, preferably a reduction in friction,
iii) Effect as a barrier coating against the permeation of gases,
iv) Effect as a barrier coating against diffusion or extraction of components of the substrate,
v) Effect as thermal barrier,
vi) Anti-fouling effect,
vii) Reduced adhesion of cells,
viii) Anti-microbial effect,
ix) Adhesive or adhesion-improving properties,
x) Change in the surface roughness, preferably a reduction of the surface roughness,
xi) Change in the chemical properties of the surface, in particular, an increase in the chemical resistance, for example, against etching,
xii) Protection against scratches,
xiii) Optical functions, such as:
   reflective or
   antireflective effect,
   semitransparency,
   transparency,
   decorative effects,
xiv) Conductive coatings with higher electrical or thermal conductivity compared with the substrate.

The precursors that can be used or first process gas components can be divided into the following groups:

Group I): Precursors with Low Vapor Pressure.

To these belong
a) Polyethers, like the already mentioned tetraethylene glycol dimethyl ether for protein-rejecting coatings on vials, sprayers, and cartridges, as well as
b) organometallic precursors for barrier coatings, for example, vials, sprayers, and cartridges, as well as for optically functional coatings.

Group II): Precursors with Average or High Vapor Pressure.

To these belong
a) Organosilicides, such as HMDSO, TMDSO,
b) Metal halogenides, for example, for optically functional coatings or barrier coatings, coatings, such as TiCl₄, SiCl₄,
c) Siloxanes, such as APS, DETA.

The invention will be explained below in greater detail using embodiments and with reference to the accompanying drawings.

Shown are:

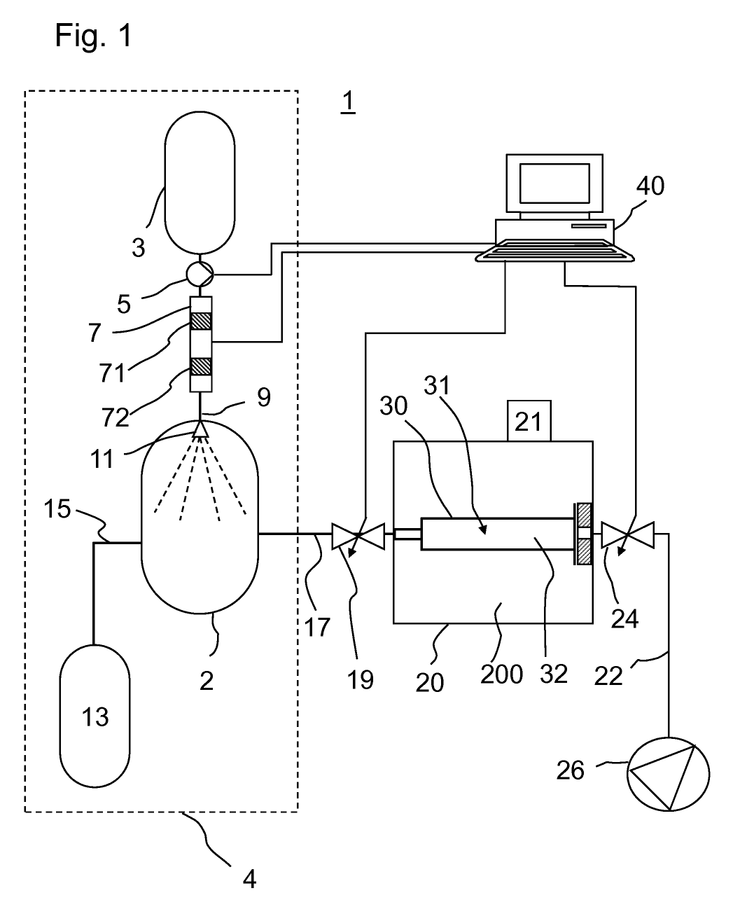

FIG. 1, a schematic configuration of a coating device according to the invention,

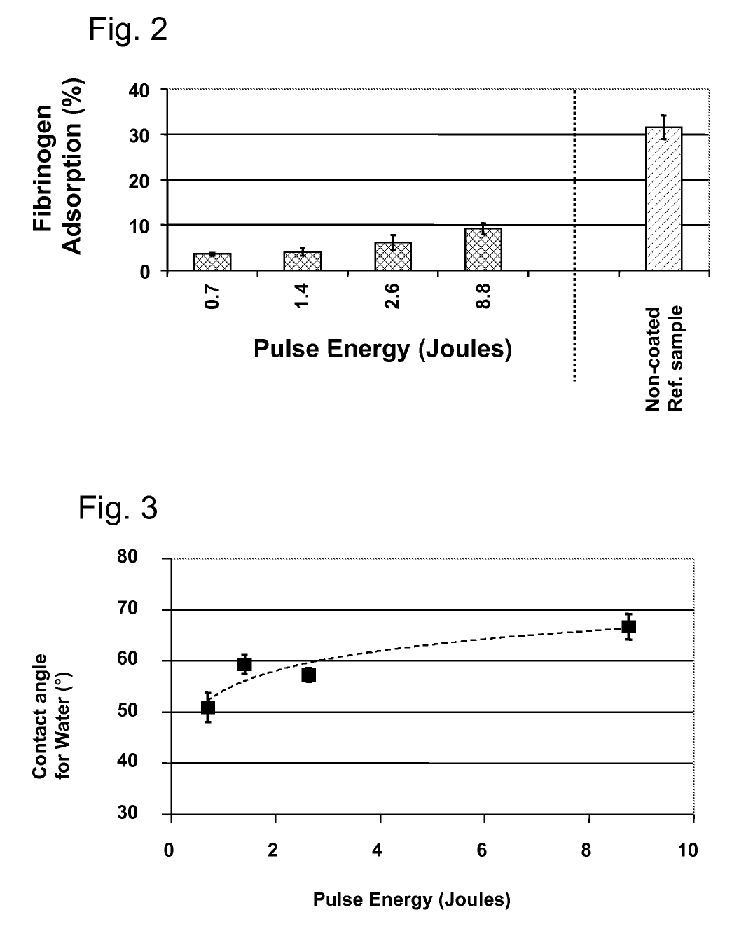

FIG. 2, a diagram of fibrinogen adsorption on polyethylene glycol coatings produced according to the invention,

FIG. 3, measurement values of the contact angle of water on polyethylene glycol coatings produced according to the invention,

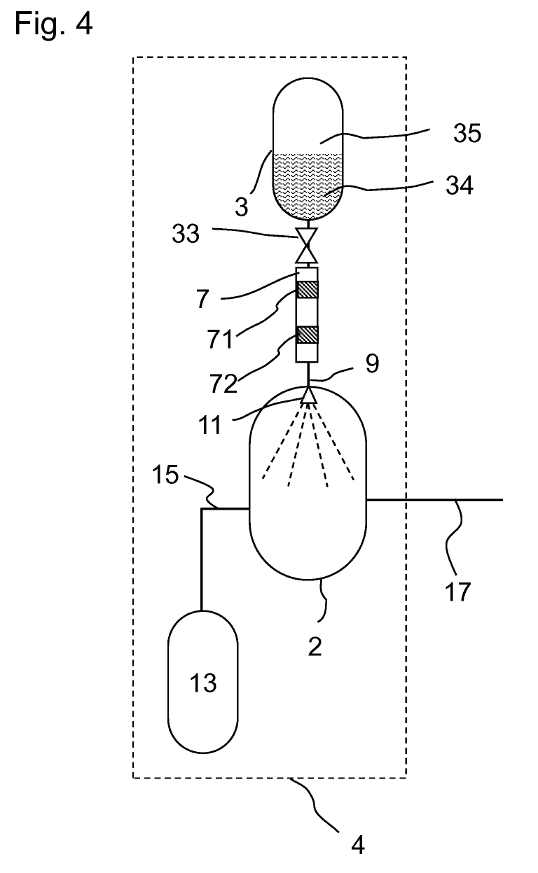

FIG. 4, an embodiment of a gas generator.

In FIG. 1, the configuration of a device 1 for plasma-supported CVD coating of work pieces is shown. The basic principle of this device is based on the fact that a layer is deposited on a work piece, in that at least one component for producing the layer is metered, wherein this component is located in a liquid phase during the metering and is transformed at least partially into a different aggregate state in a subsequent processing step.

Device 1 comprises, as central components, a reactor 20 and a gas generator 4 with an evaporator 2. Furthermore, the gas generator 4 comprises a liquid reservoir 3 with a first liquid process gas component. A fluid feeding device 5 feeds the first liquid process gas component through a feed line 9 to a nozzle 11 in the evaporator 2. As the fluid feeding device, a pressurization of the reservoir 3 can also be used, for example. In the nozzle 11, the first liquid process gas component is sprayed, in order to reach quick evaporation through the formation of small drops.

By means of another feed line 15, an inert gas is led as a second process gas component from a container 13 into the evaporator 2 and there mixed with the evaporated first process gas component; thus the process gas used for the layer deposition is created. According to the layer and precursor to be deposited, alternatively or additionally a reactive gas can also be supplied.

In the interior 200 of the reactor 20, a work piece 30 is arranged. The work piece 30, here, for example, a spray body, has a hollow body construction and is to be coated on the inside. For this purpose, the interior 31 of the work piece 30 is connected at a discharge line 22 to a pump 26 and evacuated. If the wall of the work piece 30 is sufficiently thick, the surroundings of the work piece can also remain at normal pressure. On the other hand, the surroundings are also evacuated until the pressure difference is adapted to the mechanical load capacity of the work piece and, as long as no plasma is to be ignited on the outside, the pressure for ignition of the plasma is either too small or too large.

The process gas generated in the evaporator 2 with the first and second process gas component is fed to the evacuated region of the reactor 20, that is, to the interior 31 of the work piece 30. An energy source, for example, a microwave source 21, generates an electromagnetic field that is emitted into the interior 200 of the reactor. By means of the electromagnetic field, a plasma is ignited in the evacuated region of the reactor filled with the process gas, wherein a coating is deposited on the work piece 30 with the reaction products of the first process gas component forming in the plasma. The interior 31 forms, accordingly, a reactive zone 32 in which reaction products are generated that are deposited as a coating on the work piece. As an alternative to a microwave source, a mid-frequency or radio frequency source may also be used for generating the plasma.

The coating process is controlled by means of a control device 40, in that the mass flow of the first process gas component into the reactor is controlled by means of a control of the flow of liquid process gas component into the evaporator. Typical mass flows lie in the range of 0.0005-2000 g/h, preferably in the range of 0.05 g/h-50 g/h, especially preferably in the range of 0.1 g/h-20 g/h. For the corresponding volume flows, typical ranges lie between 5 nL/min-1000 μL/min, preferably between 10 nL/min-100 μL/min, especially preferably between 20 nL/min-10 μL/min.

A control of the pressure in the coating region is realized by means of a choke 24 controlled by the control device 40 in the discharge line 22 to the pump 26.

It is useful to also provide a valve 19 in the feed line 17 from the evaporator 2 to the reactor 20 that can also be controlled, as in the shown example, by the control device 40. Thus, when the work pieces 30 are removed and inserted and during the evacuation performed before the coating, the evaporator can be blocked. Controlling the mass flow of the first process gas component or the process gas produced in the evaporator, however, preferably does not take place here. Therefore, the valve 19 can be constructed simply as a switch valve.

For this purpose, the flow is measured by means of a mass flow sensor 7 in the feed line 9 and the measurement values are transmitted to the control device 40. The mass flow sensor 7 comprises two temperature sensors 71, 72 that are arranged spaced along the flow direction in the feed line 9 and with which a temperature gradient is measured. A heating source is provided, in order to supply local heat and to generate a temperature gradient along the direction of flow. For example, the temperature sensors 71, 72 may be constructed as current-heated resistive elements. The desired value is set by controlling the liquid conveying device 5. Alternatively or additionally, a control valve may also be provided. This is sensible, for example, when the first liquid process gas component is fed by pressurizing the reservoir 3 into the evaporator 2.

The energy source, in the shown example, the microwave source 21, is also controlled by the control device, in order to control, among other things, the start and end times of the deposition process.

FIGS. 2 and 3 show properties of pharmaceutical glass vials coated with protein-repellant coatings by means of the method according to the invention.

The coatings were deposited by CVD deposition with tetraethylene glycol dimethyl ether as the process gas component, wherein the liquid metering according to the invention was used. The precursor was here stored in the reservoir at room temperature. The deposition took place through plasma polymerization in a pulsed plasma.

FIG. 2 here shows, in a diagram, measurement values of fibrinogen adsorption on protein-repellant polyethylene glycol coatings, as well as a reference value to an uncoated vial. The coatings were deposited with different pulse energies in the range between 0.7 and 8.8 Joules.

With reference to FIG. 2 it is to be seen that a significant reduction of protein adsorption with the coatings deposited according to the invention can be achieved.

FIG. 3 shows the contact angle of water on the coated vials.

With reference to the figures, a significant dependency of the pulse energy is to be recognized. The fibrinogen adsorption increases with increasing pulse energy. The contact angle also increases. The contact angle for water here varies from 51° at a low pulse energy of 0.7 Joules up to an angle of 66.7° at a pulse energy of 8.75 Joules. Layers deposited with lower energies consequently have hydrophilic properties that contribute to low protein adsorption.

In general, according to one improvement of the invention, under consideration of the above results, it is provided that a pulsed plasma is used, in order to deposit protein-repellant polyethylene glycol coatings or polyethylene glycol-like coatings or layers with tetraethylene glycol dimethyl ether as the process gas component, wherein a low pulse energy is used, wherein the pulse energy does not exceed 3 Joules.

Pulsed plasmas are here generally preferred, without limitation to the previous examples.

The production of the samples to which FIGS. 2 and 3 refer is explained in greater detail below as an embodiment.

The liquid precursor tetraethylene glycol dimethyl ether is stored at room temperature in a closed container and is pressurized by an inert gas. In this connection, any gas that does not react or not to a significant degree with the first liquid process gas component in the reservoir is suitable as the inert gas.

The precursor flows into the liquid metering system, wherein the flow is measured with a thermal mass flow sensor with thermocouples as temperature sensors. With a subsequent control valve, the desired value of the mass flow is set. The precursor remains fluid during this metering process. Argon gas is supplied to the evaporator and is used as carrier gas. The argon gas then forms the process gas used for the deposition together with the precursor. Two glass vials with 10 millimeters total volume are inserted into a double-chamber reactor and simultaneously evacuated up to a base pressure less than 0.1 mbar.

The mass flow of the tetraethylene glycol dimethyl ether is set by means of the control valve to 0.95 gram/h. For the carrier gas, in parallel a flow of 1.6 sccm is set, so that after evaporation, there is a precursor concentration of 52 vol % in the process gas.

According to a first heating and processing step, the vials are heated to a processing temperature of 120° C. by means of an argon plasma. The plasma is maintained with a pulsed microwave source with a microwave frequency of 2.45 GHz and an average power of 250 watts per vial. In this way, an argon mass flow of 50 sccm per vial and a processing pressure of 0.2 mbar are set.

In a second step directly after the heating, the process gas is introduced from the evaporator into the reactor or into the vial arranged therein, wherein a process gas pressure of 0.2 mbar is set.

The output of the microwave source at the same frequency of 2.45 GHz is distributed into the two chambers of the reactor and a plasma in the process gas is ignited in the two vials.

Four different pulse energies corresponding to the measurement values are shown in FIGS. 2 and 3. The processing parameters are indicated in the following table:

| Series No. | Coating No. | Pulse energy (Joules) | Number of samples |
|---|---|---|---|
| 1 | layer1 | 0.7 | 14 |
| 2 | layer2 | 1.4 | 14 |
| 3 | layer3 | 2.6 | 14 |
| 4 | layer4 | 8.8 | 14 |

In all of the deposition processes, coatings with a thickness of approximately 50 nanometers on the inside of the vials were produced.

FIG. 4 shows a configuration of a gas generator 4, how it may be used instead of the gas generator shown in FIG. 1.

For this embodiment, there is no fluid feeding device 5. Instead, the reservoir 3 is pressurized by filling an inert gas 35 into the reservoir until a certain high pressure is established in the container. The first liquid process gas component 34 then flows through the line 9 to the nozzle 11 due to the high pressure. The control of the mass flow is here realized by means of a control valve 33 that is connected to the control device 40 and controlled by the control device 40.

1. Method for vapor phase deposition of layers on a work piece (30), comprising:
providing a liquid reservoir (3) with a first liquid process gas component (34);
supplying the liquid process gas component (34) via a metering device (5, 33) to an evaporator (2);
evaporating and transforming, into the gas phase, the first liquid process gas component (34) in the evaporator (2), resulting in a first gaseous process gas component;
feeding the first gaseous process gas component to a reactor (20),
generating a reactive zone (32) with the first process gas component, by means of an energy source (21) in the filled region of the reactor (20), wherein a coating is deposited on the work piece (30) with the reaction products of the first process gas component forming in the reactive zone (32);
characterized by controlling the mass flow of the first process gas component (34) into the reactor (20) by means of a control device (40) acting on the metering device through a control of the flow of the liquid process gas component (34) into the evaporator (2).

2. Method for plasma-supported vapor phase deposition of layers on work pieces (30), comprising:
evacuating a reactor (20) that contains a work piece (30) to be coated, by means of a pump (26);
feeding the first gaseous process gas component to the evacuated region of the reactor (20); and
igniting a plasma in the evacuated region of the reactor (20) filled with the first gaseous process gas component, by means of an electromagnetic field, wherein a coating is deposited on the work piece (30) with the reaction products of the first process gas component forming in the plasma.

3. Method according to claim 1 characterized in that the volume flow set by the metering lies in the range of 5 nL/min-1000 μL/min.

4. Method according to claim 1 characterized in that the metering accuracy of the liquid volume flow lies in the range below 30 μL/min.

5. Method according to claim 1 characterized in that the first process gas component is mixed with a second process gas component to form a process gas mixture, wherein the mixture of the first and second process gas components is performed in the evaporator (2).

6. Method according to claim 1 characterized in that the flow of liquid process gas component (34) in its feed line (9) to the evaporator (2) is measured with a mass flow sensor (7).

7. Method according to claim 1 characterized in that the evaporation rate of the liquid process gas component (34) in the evaporator (2) is set higher than the inflow of liquid process gas component (34).

8. Method according to claim 1 characterized in that the pressure in the reactor (20) is controlled by means of a choke (24) in the discharge line from the reactor (20) to the pump (26).

9. Method according to claim 1 characterized in that, as the first process gas component, a metastable substance is used that is not stable at the vaporization temperature in the evaporator (2) or at 130° C.

10. Method according to claim 1 characterized in that a mixture of at least 2 components is metered fluidly.

11. Method according to claim 1 characterized in that a first process gas component (34) is evaporated and fed to the reactor (20) that has a vapor pressure less than 10,000 mbar at a temperature of 130° C.

12. Method according to claim 1 characterized in that a polyether is evaporated as a component of the first process gas component (34), the method further comprising using a pulsed plasma and depositing a polyethylene glycol-containing or polyethylene glycol-like coating on the work piece (30) using a pulse energy that does not exceed 3 Joules.

13. Device (1) for deposition of layers on work pieces (30), the device comprising:
a liquid reservoir (3) for a first liquid process gas component (34);
a metering device (5,33);
an evaporator (2) for evaporating and transforming, into the gas phase, the first liquid process gas component (34);
a line for supplying the liquid process gas component (34) to the evaporator (2);
a reactor (20) constructed for receiving a work piece (30) to be coated;
a gas discharge port (22) connected to the reactor (20) by means of which the liquid decomposition products can be removed from the coating region of the reactor (20);
a feed line (17) for supplying the first gaseous process gas component evaporated in the evaporator (2) to the reactor (20); and
an energy source (21) that is connected to the reactor (20), in order to generate a reactive zone in the region of the reactor (20) filled with the first process gas component, so that a coating is deposited on the work piece (30) with the reaction products of the first process gas component forming in the reactive zone;
characterized by a control device (40) for controlling the mass flow of the first process gas component into the reactor (20), wherein the control device (40) is constructed to control the flow of the liquid process gas component (34) into the evaporator (2) by means of the metering device (5,33) for setting the mass flow.

14. Device (1) for plasma-supported vapor phase deposition of layers on work pieces (30), the device comprising:
a liquid reservoir (3) for a first liquid process gas component (34);
an evaporator (2) for evaporating and transforming, into the gas phase, the first liquid process gas component (34);
a line for supplying the liquid process gas component (34) to the evaporator (2);
a reactor (20) constructed for receiving a work piece (30) to be coated;
a pump (26) connected to the reactor (20), in order to evacuate the coating region of the reactor (20);
a feed line (17) for supplying the first gaseous process gas component evaporated in the evaporator (2) to the reactor (20); and
a source (21) of an electromagnetic field, the source being connected to the reactor (20), in order to ignite a plasma in the evacuated region of the reactor (20) filled with the first process gas component by means of the electromagnetic field generated by the source, so that a coating is deposited on the work piece (30) with the reaction products of the first process gas component forming in the plasma;
characterized by a control device (40) for controlling the mass flow of the first process gas component into the reactor (20), wherein the control device (40) is constructed to control the flow of the liquid process gas component (34) into the evaporator (2) for setting the mass flow.

15. Device according to claim 13 characterized by a choke (24) communicating with the control device (40) in the discharge line from the reactor (20) to the pump (26), wherein the control device (40) is constructed to control the pressure in the reactor (20) by means of the choke (24).
